(19) United States
(12) Patent Application Publication
(10) Pub. No.: US 2004/0091120 A1
(43) Pub. Date: May 13, 2004

(54) Method and apparatus for improving corrective audio equalization

(76) Inventors: Kenneth L. Kantor, Benicia, CA (US); Andrew David Unruh, San Jose, CA (US)

Correspondence Address: GALLAGHER & LATHROP, A PROFESSIONAL CORPORATION, 601 CALIFORNIA ST, SUITE 1111, SAN FRANCISCO, CA, 94108, US

(21) Appl. No.: 10/293,909

(22) Filed: Nov. 12, 2002

(51) Int. Cl. H03G 3/00; H03G 5/00; H03G 9/00

(52) U.S. Cl. 381/61; 381/98; 381/102

(57) ABSTRACT

Acoustical characteristics of rooms or other environments in which audio systems operate may be improved by equalization derived from measures of relative acoustic energy storage of the audio system such as a Relative Acoustic-energy Decay Spectrum (RADS). A RADS may be calculated from a measure of absolute energy storage such as RT60 values obtained from models or measurements of the audio system, and normalized with respect to a measure of acoustic energy storage of a reference system.

### TECHNICAL FIELD

The present invention is related to the field of audio systems and acoustics, and pertains more specifically to improving the perceived performance of an audio system by compensating for acoustical characteristics of rooms or other environments in which audio systems operate.

### BACKGROUND ART

The general principle of corrective “equalization” in audio systems is well-known. Implicit in any equalization process is the existence of a target response that an ideal system of the type in question should exhibit. This target response is specified by objective metrics, and the process of equalization provides benefits if approaching the target response will reliably improve the sound quality perceived by a listener. One example of such an objective metric is a flat amplitude response in the transfer function describing a music reproduction system. Equalization is typically achieved by filters in the audio chain that are adjusted until the overall system response is as flat as desired.

A traditional approach used in audio systems is based on linear systems theory and attempts to compensate for deviations from a flat frequency response by determining the transfer function H(ω) of a particular audio system for a particular location, deriving an equalizing filter having a transfer function G(ω) that is the inverse of H(ω), and applying the equalizing filter to signals within the system so that the overall audio system has a flat frequency response. Such traditional approaches often provide some degree of subjective improvement, but much greater improvement is both desirable and possible.

Towards this goal, there have been attempts to characterize and equalize audio system behavior in the time domain. In this case, the system target response function is an idealized impulse response, and the equalization process is achieved by determining and applying an inverse time domain function to counteract undesirable temporal features such as those features that might arise from room reflections.

Unfortunately, no known methods of equalization are capable of obtaining the desired subjective results reliably. Very complex equalization methods combining time- and frequency-domain measurements have been tried, but these methods still fail to consistently deliver beneficial results in such activities as, for example, loudspeaker design or concert hall equalization. Furthermore, such techniques can result in unpredictable deterioration of the final subjective sound quality that requires human monitoring. As a result these techniques are not suitable for automated applications.

It has been recognized by some practitioners that what is required to improve the equalization process is to identify measurable parameters of sound signals that properly relate physical system behavior to human perceptions. Towards this end, various methods of data windowing, averaging or weighting have been attempted with the intent of identifying a method that closely mimics the human auditory system's assessment of such qualities as tonal balance, timbre, and spatial envelopment. Some of these methods demonstrate improvement over traditional approaches, but even the most successful of the equalization methodologies have encountered the same limitations mentioned above; they do not adequately characterize how the human auditory system perceives sound and they are apt to produce inconsistent results.

The inventors have identified several features of traditional approaches they believe are inherent limitations that impede further improvement. Some of these limitations are discussed in the following paragraphs.

Perhaps the most fundamental limitation is the fact these approaches characterize the target response in terms of a single amplitude spectrum and attempt to achieve equalization by forcing the frequency response of a particular audio system into compliance with a target frequency response. These approaches assume a deterministic inverse function exists that can be applied to a signal to achieve an ideal spectral or temporal characteristic. Unfortunately, this assumption is not true in general, which causes the traditional approaches to suffer from a number of problems.

Because the frequency response and, therefore, the equalization provided by traditional approaches are affected by sound that arrives directly from the loudspeaker as well as from reflections on one or more surfaces in the room, the appropriate equalization changes dynamically over the duration of the audio system impulse response. This makes proper correction impossible to achieve with simple filters. Furthermore, the loudspeaker and room combination yields a sound field that is very sensitive to listener position. The transfer function H(ω) of a typical loudspeaker-room combination is a function of position as well as frequency, and this transfer function varies significantly for changes in position that are as small as the distance between a person's ears. Even if a particular equalization filter can achieve a flat response for one point within a room, that same filter probably will not achieve a flat response for any other point within that room.

Yet another limitation in the traditional approaches is the assumption that a conventional target response can be achieved by merely adjusting spectral energy levels in the signals that are used to drive a loudspeaker. This assumption fails because the equalizing transfer function typically has mathematical singularities for which there are no solutions that can be implemented with real systems and components. Furthermore, an audio system often exhibits so called “excess phase” that renders the inverse function non-deterministic.

The present invention is directed toward improving the perceived performance of an audio system by using an entirely different representation of the target response. This representation appears to provide a model of how the human auditory system perceives tonal balance or timbre that is more accurate than a traditional frequency response amplitude spectrum, and it is applicable to both source audio signals and audio systems, including the acoustical environments in which audio systems operate. The present invention may be applied to essentially any aspect of an audio system; however, this disclosure refers more particularly to loudspeakers and the acoustical environments in which the loudspeakers are situated.

### DISCLOSURE OF INVENTION

It is an object of the present invention to provide improved methods and devices for improving the perceived performance of audio systems that transcend the limitations of known traditional approaches.

According to one aspect of the present invention, an audio system includes circuitry that provides correction for an acoustic signal with respect to a model of perceived timbre derived from a measure of relative acoustic energy storage of the acoustical system that varies as a function of frequency and is normalized with respect to a reference measure of acoustic energy storage that varies as a function of frequency.

According to another aspect of the present invention, a model of perceived timbre is derived by obtaining a measure of relative acoustic energy storage within an acoustical system that varies as a function of frequency, normalizing the measure of relative acoustic energy storage with respect to a reference measure of acoustic energy storage that varies as a function of frequency, and deriving the model from the normalized measure of relative acoustic energy storage.

The various features of the present invention and its preferred implementations may be better understood by referring to the following discussion and the accompanying drawings. The contents of the following discussion and the drawings are set forth as examples only and do not limit the scope of the present invention.

### BRIEF DESCRIPTION OF DRAWINGS

FIG. 1 is a block diagram of an audio system in which various aspects of the present invention may be incorporated.

FIG. 2 is a graphical illustration of a spectral-magnitude response as a function of frequency for a hypothetical audio system.

FIG. 3 is a graphical illustration of a spectral-magnitude response as a function of frequency and time for the hypothetical audio system.

FIG. 4 is a graphical illustration of the spectral-magnitude response of a conventional correction filter for the hypothetical system response shown in FIG. 1.

FIGS. 5-6 are graphical illustrations of the corrected spectral-magnitude response of the hypothetical audio system provided by the conventional corrective filter response shown in FIG. 4.

FIG. 7 is a graphical illustration of the spectral-magnitude response of a correction filter according to the present invention for the hypothetical system response shown in FIG. 1.

FIGS. 8-9 are graphical illustrations of the corrected spectral-magnitude response of the hypothetical audio system provided by the corrective filter response shown in FIG. 7.

### MODES FOR CARRYING OUT THE INVENTION

### Overview

A block diagram of a typical audio system is shown in FIG. 1. A source 10 such as a microphone, radio receiver or compact disc (CD) player provides an audio signal to an amplifier 20, which amplifies the audio signal into an output signal having enough power to drive an acoustic output transducer 30 such as a loudspeaker. Many variations are possible and no special significance is intended by showing the amplifier 30 as one distinct component rather than some other arrangement such as separate preamplifier and power amplifier components or as components that are integrated with the source 10 or the acoustic output transducer 30, for example.

Although it is anticipated that the present invention may be conveniently implemented in the amplifier 20, various features of the present invention may be incorporated into essentially any component of an audio system. The present invention may be implemented by analog and/or digital technologies in a wide variety of forms including discrete and integrated electronic components, programmable logic, and program-controlled devices. Program implementations may be conveyed by essentially any machine-readable information storage media including magnetic and optical discs, read-only memory and programmable memory.

Referring to FIG. 1, the acoustic output transducer 30 is situated in a listening environment 40 that has intrinsic acoustical characteristics. The listening environment 40 may be completely enclosed, completely open, or any variation in between these two extremes. In the following discussion, the term “room” generally refers to a listening environment that is completely or substantially enclosed, such as by walls, a floor and a ceiling. It should be understood, however, that aspects of the present invention described with references to rooms are applicable to any listening environment.

### Traditional Equalization for Total System Response

The overall response of the audio system shown in FIG. 1 can be characterized by the responses of the amplifier 20 and the acoustic output transducer 30 in combination with the response of the listening environment 40. This overall system response usually deviates from some ideal target response and traditional methods have attempted to provide some type of equalization that forces the system response into conformity with the ideal target response.

These traditional methods typically characterize an audio system as a linear time-invariant system represented by the expression

y(t)=h(t)*x(t) (1)

where t=time;

x(t)=the input signal as a function of time;

y(y) the acoustic output signal as a function of time;

h(t)=the impulse response of the system; and

the star symbol (*) denotes convolution.

Expression 1 can be rewritten in terms of a frequency-domain representation as follows:

Y(ω)=H(ω)·X(ω) (2)

where (ω)=frequency;

X(ω)=a frequency-domain expression of the input signal;

Y(ω)=a frequency-domain expression of the acoustic output signal;

H(ω)=the transfer function of the system; and

the dot symbol (·) denotes multiplication.

Traditional approaches have attempted to provide equalization by deriving a filter or other signal processor that has a transfer function G(ω) equal to the inverse of H(ω). This has been attempted by first obtaining the system transfer function H(ω) and then calculating its inverse. The system transfer function H(ω) is typically derived by driving the audio system with an input audio signal x(t), measuring the acoustic signal y(t) generated in the listening environment 40 by the acoustic output transducer 30, obtaining a frequency-domain representation Y(ω) of the measured acoustic signal, obtaining a frequency-domain representation X(ω) of the input audio signal, and deriving the system transfer function from the expression:

$$H ( ω ) = \frac{Y ( ω )}{X ( ω )} \qquad ( 3 )$$

For ease of explanation, this discussion omits consideration of the transfer function for the components that are used to measure the acoustic output signal.

In typical implementations, an equalization component having a transfer function G(ω)=H⁻¹(ω) is incorporated into the amplifier 20 so that the overall system response is equalized into a transparent function as follows:

Y(ω)=G(ω)·H(ω)·X(ω)=H⁻¹(ω)·H(ω)·X(ω)=X(ω) (4)

Although this approach appears to succeed mathematically, the equalization it provides in practical systems has not been satisfactory for a number of reasons.

One reason is that the transfer function for a typical audio system is affected by reflections from one or more surfaces in the listening environment 40. The system transfer function H(ω) is very sensitive to position and, consequently, the inverse equalization transfer function G(ω)=H⁻¹(ω) is also sensitive to position. Either of these transfer functions varies significantly for changes in position that are as small as the distance between a person's ears. As a result, even if an equalization transfer function G(ω) can achieve a flat frequency response for one point within the listening environment 40, that same equalization transfer function probably cannot achieve a flat response for every other point within even a small portion of that listening environment.

Another reason that traditional approaches have failed arises from an incorrect assumption that a flat frequency response can be achieved by merely adjusting spectral energy levels in the signal that is used to drive the acoustic output transducer 30. This assumption is incorrect because the equalization transfer function G, which is the inverse of the system transfer function H, typically has mathematical singularities that cannot be corrected using finite energy.

Perhaps the most significant reason that traditional approaches have not been satisfactory is because they are based on an assumption that timbre as perceived by the human auditory system can be modeled with an amplitude spectrum.

### Compensation for Only the Listening Environment

The inventors have discovered that these failures arise because traditional models for perceived timbre are incomplete and traditional approaches have attempted to solve the wrong problem. Instead of attempting to force the overall end-to-end frequency response of an audio system to conform to some ideal target response, an attempt should be made to compensate for certain acoustical characteristics that are intrinsic to only the listening environment 40, and these compensations should be based on a better model of perceived timbre. The present invention identifies and compensates for intrinsic acoustical characteristics of the listening environment 40 that affect the perceived timbre of acoustic signals and are substantially independent of position within the environment.

The inventors have determined that an improved model of perceived timbre for a listening environment is based on a measure of the environment's relative acoustic energy storage as function of frequency, which can be derived from an absolute measure of energy storage E(ω) of the environment. One expression of relative acoustic energy storage is a Relative Acoustic-energy Decay Spectrum (RADS) S(ω), which is an expression of energy storage that is independent of signal amplitude and is substantially independent of position within the environment. A RADS is an objective assessment of timbre that has been found to correlate very well with a subjective assessment of timbre by the human auditory system.

A RADS can be used to derive a variety of functions for equalization that can be used in a variety of applications. One example is the derivation of an equalization filter that can be used to raise the subjective accuracy of an audio system to levels higher than that possible by traditional approaches. The equalization filter derived in this way is based on an assessment of audio perception and is not related to the traditional inverse-response filter; thus, in addition to its reliable sound quality, an equalization filter derived according to the present invention does not introduce substantial listening-position artifacts or suffer from the effects of either excess phase or singularities in the system transfer function.

One measure of absolute energy storage E(ω) from which a RADS or other expression of relative acoustic energy storage can be derived is the time required for the energy of acoustical reflections or reverberations at a particular frequency c to decay by 60 dB. This time is referred to as reverberation time RT₆₀(ω). Yet another measure of energy storage referred to as RT₂₀(ω) expresses the time required for reverberations at frequency ω to decay by 20 dB.

In one implementation, a RADS is obtained for a particular listening environment 40 by normalizing the RT₆₀(ω) values of the listening environment with respect to a set of reference values at several frequencies {ωᵢ}. These RT₆₀ times may be normalized to essentially any reference value if desired. Preferably, adjacent frequencies in the set are separated from one another in frequency by an amount approximately equal to the so called critical bandwidths of the human auditory system.

The RT₆₀(ω) values may be determined in a wide variety of ways including the use of mathematical models like the Sabine equation that is based on environment geometry and acoustical properties of reflective surfaces within the environment. Another mathematical model comprises a set of leaky integrators in which each integrator represents energy storage characteristics of the listening environment 40 for a range of frequencies. Other techniques are empirical and use signal processing to measure reverberation times in a particular environment. The way in which the values are determined may affect the accuracy of those values, which in turn may affect system performance. In principle, however, these values may be determined using any desired method. Additional information may be obtained from “Acoustics—Measurement of the Reverberation Time of Rooms With Reference to Other Acoustical Parameters,” ISO standard 3382:1997(E), which is incorporated herein by reference.

Estimates of the RT₆₀ values for a few frequencies in three different listening environments are shown below in Table I.

TABLE I

| | RT₆₀ (seconds) | | | | | |
|---|---|---|---|---|---|---|
| | 125 Hz | 250 Hz | 500 Hz | 1 kHz | 2 kHz | 4 kHz |
| Environment 1 | 0.5 | 0.3 | 0.2 | 0.3 | 0.4 | 0.3 |
| Environment 2 | 1.0 | 0.6 | 0.4 | 0.5 | 0.4 | 0.5 |
| Environment 3 | 2.6 | 2.2 | 1.7 | 2.0 | 1.6 | 2.0 |

Environment 1 represents a room designed for home theatre applications having moderate amounts of reverberation. Environment 2 represents a typical household room that is not specifically designed for an audio system. Environment 3 represents an acoustically live auditorium or other large public forum having large amounts of reverberation.

A measure of relative acoustic energy storage S(ω) like a RADS may be derived from a measure of absolute energy storage E(ω) like RT₆₀(ω) according to the following expression:

$$S ( {ω}_{i} ) = \frac{E ( {ω}_{i} )}{R ( {ω}_{i} )} \qquad ( 5 )$$

where ωᵢ=frequency i in the set of frequencies {ωᵢ};

R(ωᵢ)=a reference energy storage at frequency ωᵢ; and

S(ωᵢ)=relative energy storage for a particular environment at frequency ωᵢ.

This measure of relative acoustic energy storage may be used to model perceived timbre and to compensate for any deviations from some set of reference values. In one implementation, an audio system adjusts its gain according to the following expression:

$$A ( {ω}_{i} ) = C ( ω ) \cdot {[ \frac{1}{S ( {ω}_{i} )} ]}^{γ} \qquad ( 6 )$$

where A(ωᵢ)=the gain applied by the audio system at frequency ωᵢ;

C(ω)=a coefficient determined empirically; and

γ=a constant determined empirically.

The coefficients C(ω) and γ may be determined for a particular audio system by psychometric listening tests designed to assess the relationship between energy storage and the perception of timbre. In these tests, the coefficients are varied until the audio system with RADS equalization sounds as similar as possible to a desired reference system. It has been found that this technique is generally able to determine coefficients for a wide variety of references and is stable across a population of listeners

In one implementation, C(ω)=1, γ=0.5, R(ωᵢ)=RT₆₀(ω) for a reference environment, and E(ωᵢ)=RT₆₀(ω) for the listening environment 40.

The coefficient C(ω) is provided to compensate for any conditions in the listening environment 40 that are not represented by the energy storage values. One example is the placement of the acoustic output transducer 30 with respect to reflective surfaces in the environment. Low frequencies can be boosted by as much as about eight times (9 dB) if the acoustic output transducer 30 is placed in a corner of a room next to the floor. Other examples include the proximity of a listener to the acoustic output transducer and the radiation pattern of the output transducer.

The constant γ controls the degree of compensation. Compensation becomes more aggressive as the value of γ is increased.

The reference environment represented by the R(ωᵢ) values can be for essentially any environment. For example, the reference can be a particular demonstration room of a business that sells loudspeakers, or it could represent a hypothetical ideal room for a particular application. If a person auditions a loudspeaker in a particular demonstration room and purchases the loudspeaker because he or she likes the way it sounds in that room, then the person could compensate for the acoustical characteristics of a listening room at home so the loudspeaker sounds the same in that listening room as it did in the demonstration room. This example underscores a principal difference between the present invention and prior traditional approaches; the present invention may be sued to compensate only for characteristics of a listening environment and need not attempt to force an audio system to have a particular overall response.

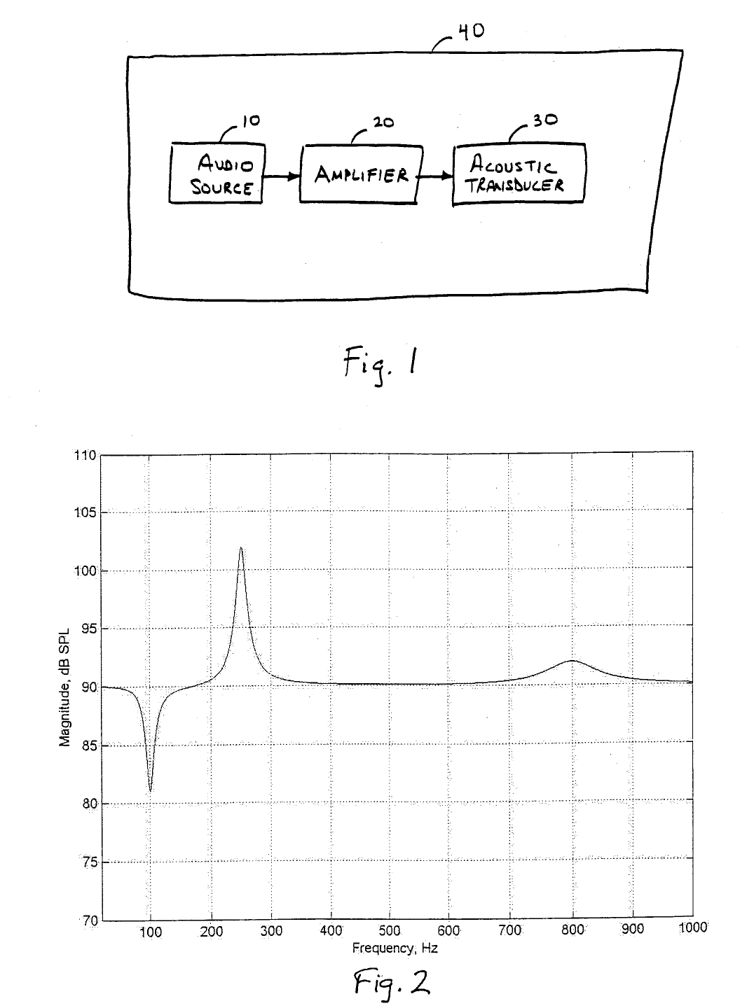

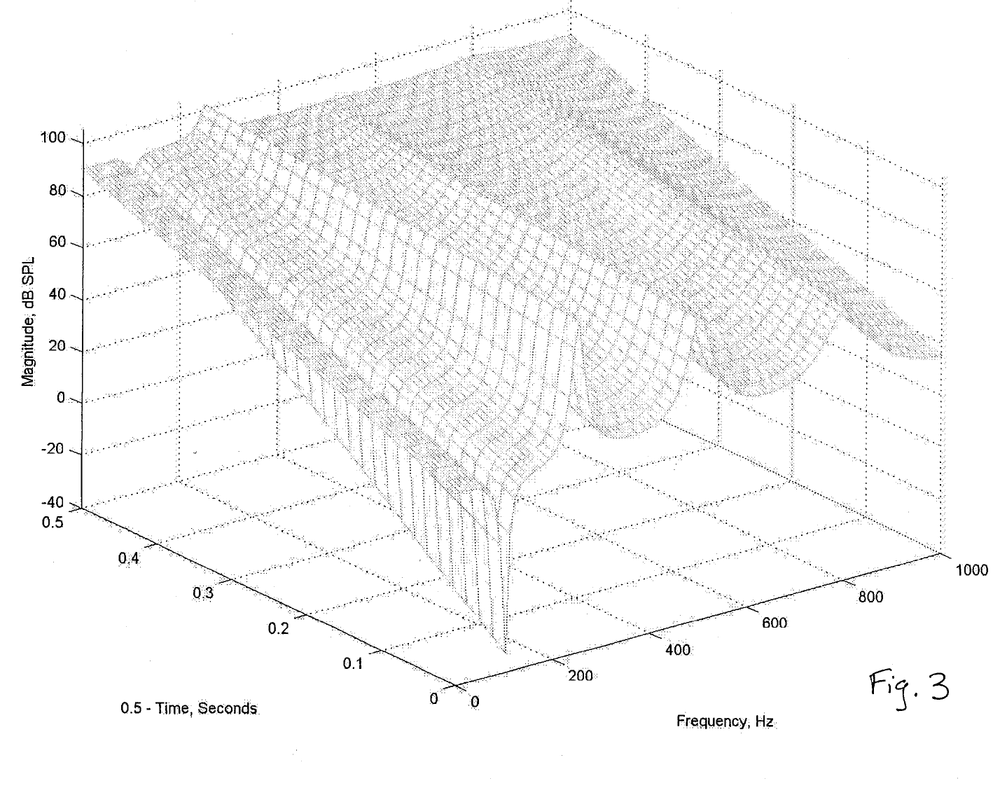

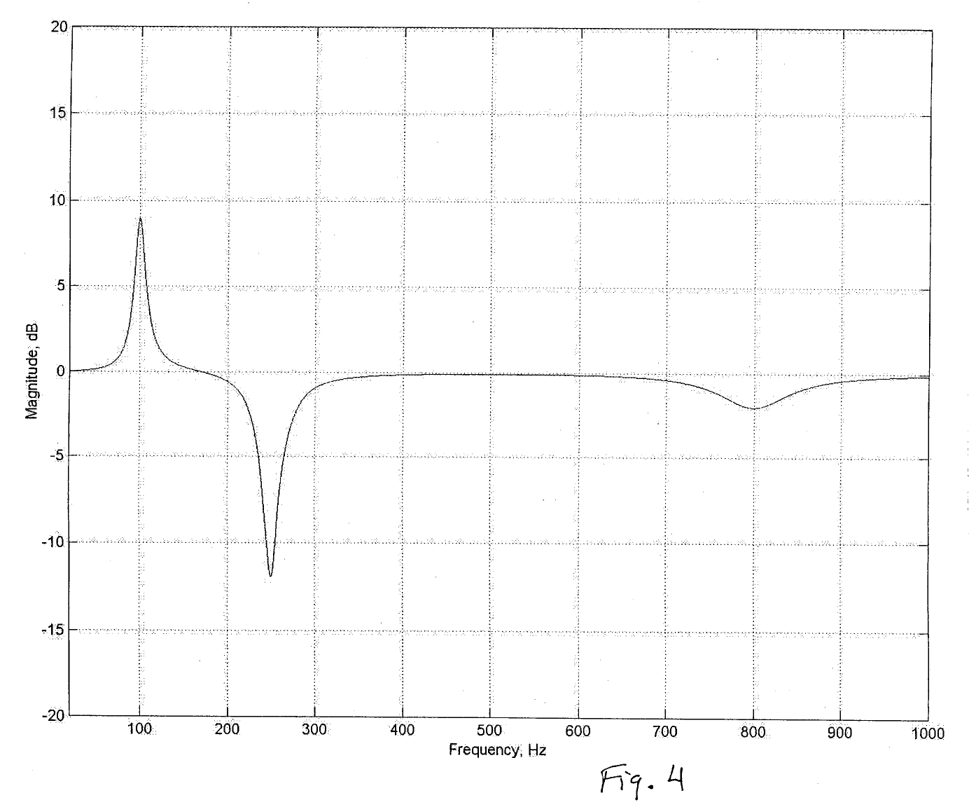

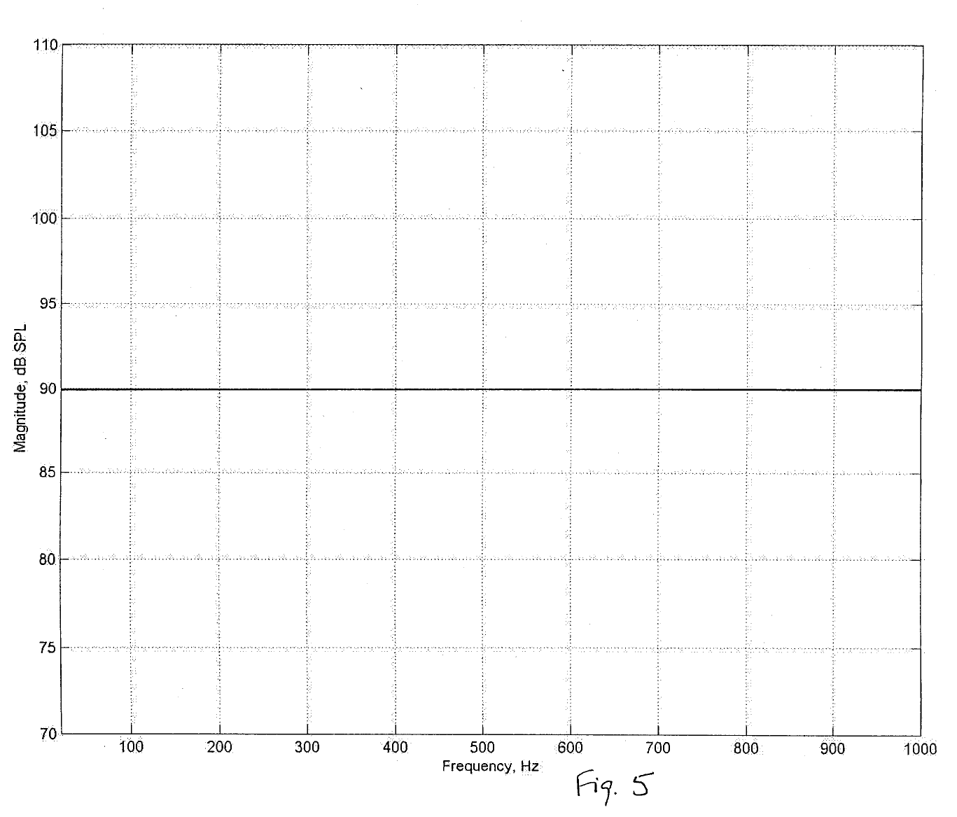

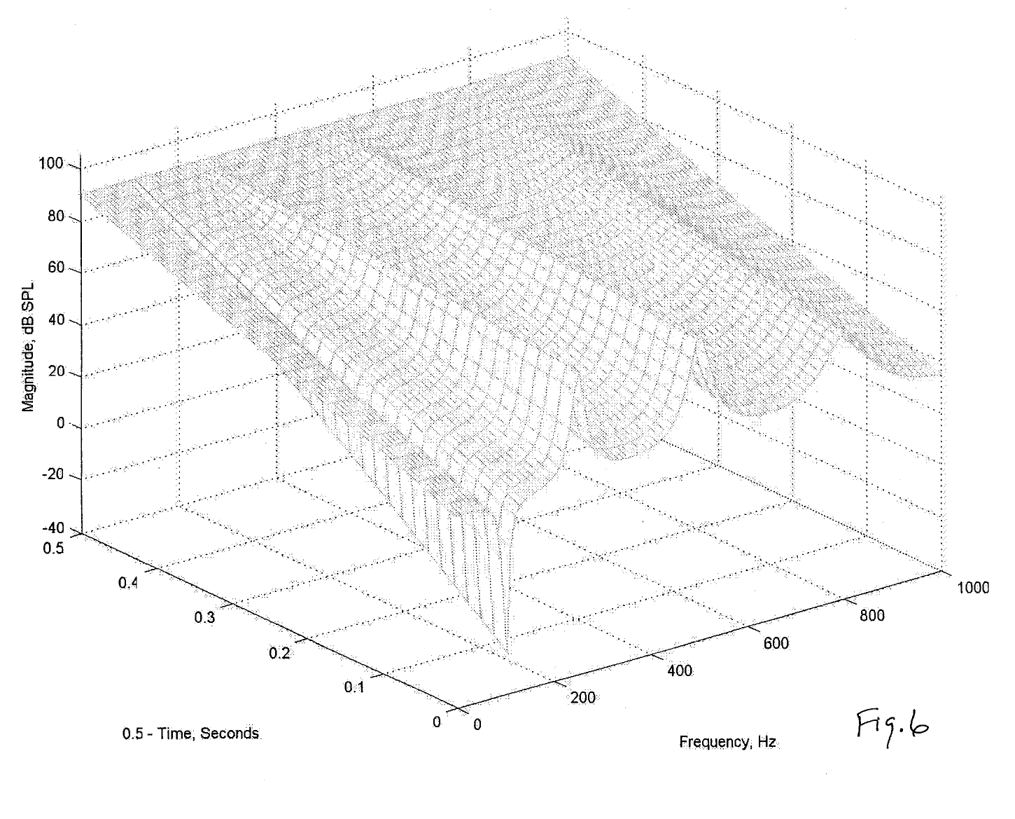

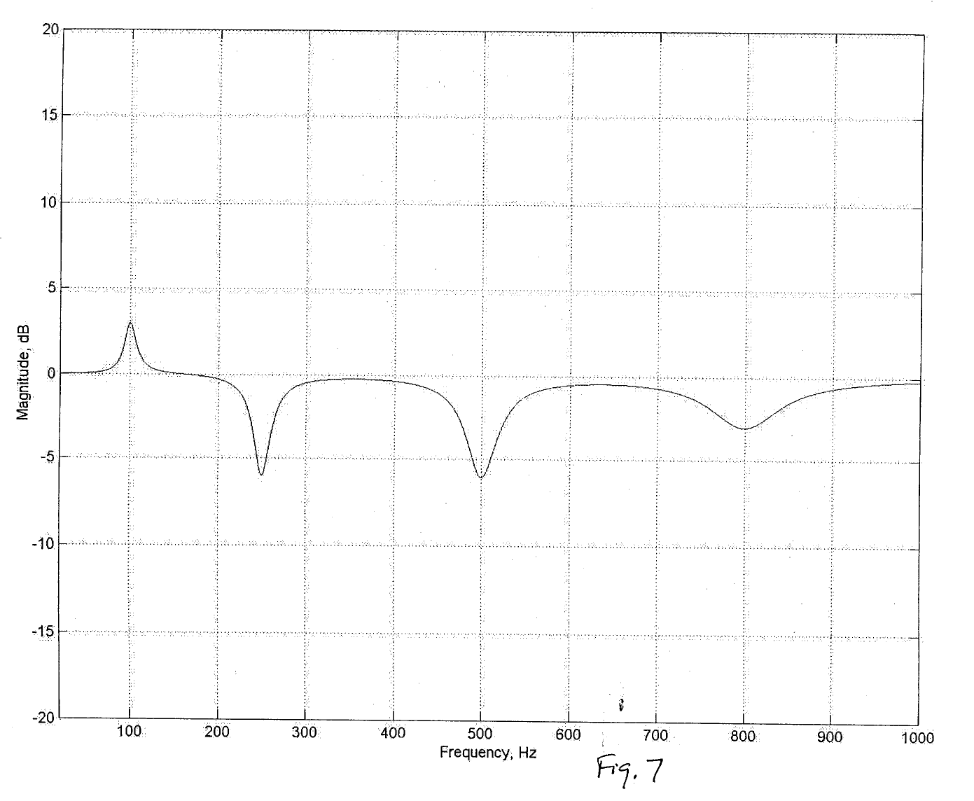

FIG. 2 illustrates the spectral-magnitude response of a hypothetical audio system as a function of frequency. A time-frequency plot of the hypothetical system response is shown in FIG. 3. Conventional approaches use a corrective filter in the system to obtain a flat response. FIG. 4 illustrates the spectral-magnitude response of a conventional correction filter for the hypothetical system response shown in FIG. 1. The flat system response obtained by this conventional filter is illustrated in FIG. 5. A time-frequency plot of the corrected system response is shown in FIG. 6. Although the corrected response is flat at a reference time zero, the energy storage characteristics of the listening environment 40 cause the corrected system response to deviate substantially from a flat response after only a few hundred milliseconds.

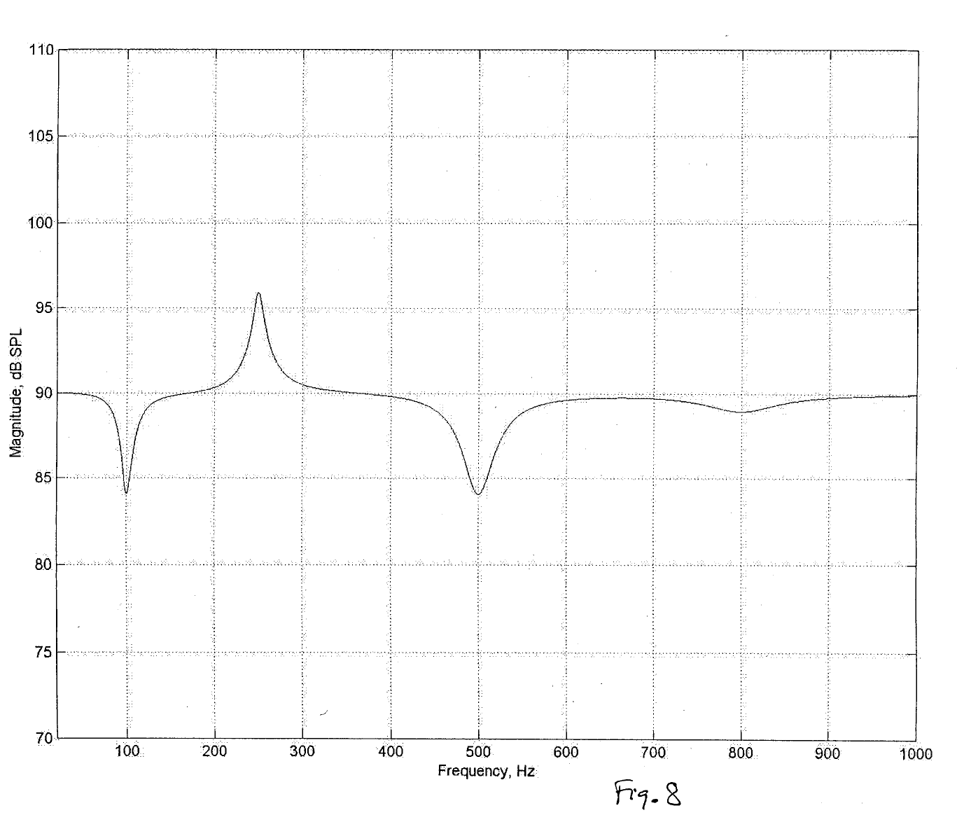

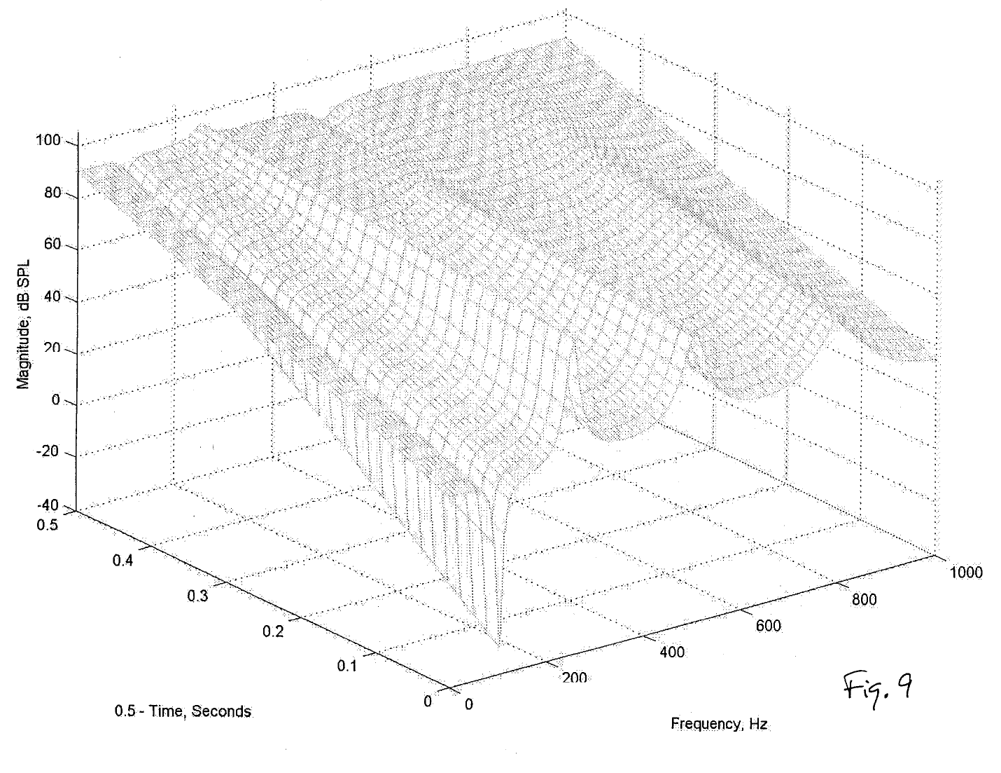

The present invention obtains an improved result by using a corrective filter that differs substantially with what is used in traditional approaches. FIG. 7 illustrates the spectral-magnitude response of a correction filter according to the present invention for the hypothetical system response shown in FIG. 1. The system response obtained by this filter is not flat, as illustrated in FIG. 8. A time-frequency plot of the corrected system response is shown in FIG. 9.

Referring to Table I, if environment 1 is selected as the reference environment, then the particular implementation of equation 6 mentioned above with C(ω)=1 and γ=0.5 yields the set of gain coefficients shown in Table II.

TABLE II

| | A(ω) | | | | | |
|---|---|---|---|---|---|---|
| | 125 Hz | 250 Hz | 500 Hz | 1 kHz | 2 kHz | 4 kHz |
| Environment 1 | 1.0 | 1.0 | 1.0 | 1.0 | 1.0 | 1.0 |
| Environment 2 | 0.707 | 0.707 | 0.707 | 0.775 | 1.000 | 0.775 |
| Environment 3 | 0.439 | 0.369 | 0.343 | 0.387 | 0.500 | 0.387 |

The compensation provided by the present invention does not promise to duplicate the listening experience with a particular acoustic output transducer and listening environment with the same transducer in another environment. This is not possible in general because the present invention does not, for example, transform an acoustically dead environment into an acoustically live environment. The present invention does, however, provide compensation that essentially duplicates a subjective appraisal of timbre from one listening environment to another that is substantially independent of position within the environments.

The model of perceived timbre that is based on a measure of relative acoustic energy storage provides a tool that can be used to identify audio system reproduction errors. Deviations between a reference level and a model for a specific system can be reduced by modifying operational characteristics of the audio system. For example, operational characteristics of an audio system can be modified by adapting compensation filters, modifying acoustic properties of a listening environment, and changing radiating properties of acoustic output transducers such as loudspeakers. The radiating patterns of a loudspeaker can be modified by changing the gain and phase of multiple loudspeakers, by selecting different loudspeaker technologies, and by changing cutoff frequencies and roll off rates of filters in crossover networks for multiple loudspeakers. An analogous approach can be used with input acoustic transducers like microphones. The model provides a tool that allows a systematic approach to making these modifications.

This systematic approach can be automated. An audio system that includes components to determine its relative acoustic energy storage can change various components to modify its operational characteristics, determine the current relative acoustic energy storage, assess the effects of the change, and continue making changes until a termination condition is reached.

1. A method that comprises:
obtaining a measure of relative acoustic energy storage within an audio system that varies as a function of frequency, wherein the measure of relative acoustic energy storage is normalized with respect to a reference measure of acoustic energy storage that varies as a function of frequency; and
deriving a model of perceived timbre of the audio system from the measure of relative acoustic energy storage.

2. The method according to claim 1 wherein the measure of relative acoustic energy storage is a relative acoustic-energy decay spectrum.

3. The method according to claim 1, wherein the audio system comprises an acoustic transducer situated in a room and the method comprises receiving a geometric and acoustic description of the room and deriving therefrom the measure of relative acoustic energy storage.

4. The method according to claim 3 that further comprises deriving a compensation filter from the model of perceived timbre that adjusts audio signal spectrum levels of signals driving the acoustic transducer to compensate for acoustic energy storage characteristics of the audio system.

5. The method according to claim 1 that comprises receiving a representation of an acoustic signal generated by an acoustic transducer in the audio system and deriving therefrom the measure of relative acoustic energy storage.

6. The method according to claim 5 that further comprises deriving a compensation filter from the model of perceived timbre that adjusts audio signal spectrum levels of signals driving the acoustic transducer to compensate for acoustic energy storage characteristics of the audio system.

7. The method according to claim 1 that comprises:
identifying differences between the derived model of perceived timbre and a reference model;
modifying acoustical characteristics of the audio system; and
iterating steps in the method until the differences satisfy a desired termination condition.

8. The method according to claim 7 that modifies acoustical characteristics of the audio system by changing a radiation pattern of an acoustic output transducer.

9. An audio system that presents acoustic signals in a listening environment, wherein the system comprises:
audio signal processing circuitry that receives an audio signal from an input, generates a compensated audio signal by applying a compensation filter to the received audio signal, and provides the compensated audio signal to an output, wherein the compensation filter compensates the acoustic signal with respect to a model of perceived timbre derived from a measure of relative acoustic energy storage of the audio system that varies as a function of frequency and is normalized with respect to a reference measure of acoustic energy storage that varies as a function of frequency; and
an acoustic transducer situated in the listening environment and coupled to the output of the audio signal processing circuitry that generates an acoustic signal in response to the compensated audio signal.

10. The audio system according to claim 9 wherein the measure of relative acoustic energy storage is a relative acoustic-energy decay spectrum.

11. The audio system according to claim 9 that comprises an acoustic transducer situated in a room, wherein the measure of relative acoustic energy storage is derived from a geometric and acoustic description of the room.

12. The audio system according to claim 9, wherein the measure of relative acoustic energy storage is derived from an acoustic signal generated by the acoustic transducer.

13. A medium readable by a device, wherein the medium carries a program of instructions that can be executed by the device to perform a method that comprises:
obtaining a measure of relative acoustic energy storage within an audio system that varies as a function of frequency, wherein the measure of relative acoustic energy storage is normalized with respect to a reference measure of acoustic energy storage that varies as a function of frequency; and
deriving a model of perceived timbre of the audio system from the measure of relative acoustic energy storage.

14. The medium according to claim 13 wherein the measure of relative acoustic energy storage is a relative acoustic-energy decay spectrum.

15. The medium according to claim 13, wherein the audio system comprises an acoustic transducer situated in a room and the method comprises receiving a geometric and acoustic description of the room and deriving therefrom the measure of relative acoustic energy storage.

16. The method medium according to claim 15, wherein the method further comprises deriving a compensation filter from the model of perceived timbre that adjusts audio signal spectrum levels of signals driving the acoustic transducer to compensate for acoustic energy storage characteristics of the audio system.

17. The medium according to claim 13, wherein the method comprises receiving a representation of an acoustic signal generated by an acoustic transducer in the audio system and deriving therefrom the measure of relative acoustic energy storage.

18. The medium according to claim 17, wherein the method further comprises deriving a compensation filter from the model of perceived timbre that adjusts audio signal spectrum levels of signals driving the acoustic transducer to compensate for acoustic energy storage characteristics of the audio system.

19. The medium according to claim 13, wherein the method comprises:
identifying differences between the derived model of perceived timbre and a reference model;
modifying acoustical characteristics of the audio system; and
iterating steps in the method until the differences satisfy a desired termination condition.

20. The medium according to claim 19, wherein the method modifies acoustical characteristics of the audio system by changing a radiation pattern of an acoustic output transducer.
